(19) United States
(12) Patent Application Publication
(10) Pub. No.: US 2022/0230850 A1
(43) Pub. Date: Jul. 21, 2022

(54) VOLTAGE AND CURRENT PROBE

(71) Applicant: LAM RESEARCH CORPORATION, Fremont, CA (US)

(72) Inventors: Hema Swaroop MOPIDEVI, Fremont, CA (US); John PEASE, San Mateo, CA (US); Ovidio Horacio ANTON, Campbell, CA (US)

(21) Appl. No.: 17/607,075

(22) PCT Filed: Apr. 29, 2020
(86) PCT No.: PCT/US2020/030416

§ 371 Date: Oct. 28, 2021

Related U.S. Application Data
(60) Provisional application No. 62/844,309, filed on May 7, 2019.

(51) Int. Cl. H01J 37/32; H01P 3/06; H01F 27/06; H01F 27/29; G01R 15/18

(52) U.S. Cl. CPC H01J 37/32183; H01J 37/32935; H01P 3/06; H01F 27/06; H01F 2027/065; G01R 15/181; H01J 37/32091; H01J 2237/24564; H01F 27/29

(57) ABSTRACT

A voltage/current probe includes: a circuit board; a first inductor that is located on the circuit board, that is wound in a first direction, and that includes: a first end connected to a first output conductor; and a second end; a second inductor that is located on the circuit board, that is wound in a second direction that is opposite the first direction, and that includes: a third end that is connected to a second output conductor; and a fourth end that is connected to the second end of the first inductor and to a third output conductor.

### CROSS-REFERENCE TO RELATED APPLICATIONS

This application claims priority to U.S. Provisional Application No. 62/844,309, filed on May 7, 2019. The entire disclosure of the application referenced above is incorporated herein by reference.

### FIELD

The present disclosure relates to substrate processing systems and more particularly to voltage and current probes for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates, such as semiconductor wafers. Example processes that may be performed on a substrate include, but are not limited to, deposition, etching, and cleaning.

A substrate may be arranged on a substrate support, such as a pedestal or an electrostatic chuck (ESC), in a processing chamber. During processing, gas mixtures may be introduced into the processing chamber and plasma may be used to initiate chemical reactions.

A controller of a substrate processing system may be configured to control gas flow to and from the processing chamber. The controller may also be configured to control power applied to one or more electrodes located in the processing chamber, such as to strike plasma. The controller may control power applied to one or more electrodes based on one or more voltage and/or current measurements.

### SUMMARY

In a feature, a voltage/current probe includes: a circuit board; a first inductor that is located on the circuit board, that is wound in a first direction, and that includes: a first end connected to a first output conductor; and a second end; a second inductor that is located on the circuit board, that is wound in a second direction that is opposite the first direction, and that includes: a third end that is connected to a second output conductor; and a fourth end that is connected to the second end of the first inductor and to a third output conductor.

In further features: the circuit board includes a first surface and a second surface that is opposite the first surface; the first inductor is located on the first surface; and the second inductor is located on the second surface.

In further features: the first output conductor and the third output conductor are located on the first surface; and the second output conductor is located on the second surface.

In further features, the fourth end is connected to the second end of the first inductor through a via through the circuit board.

In further features: the first inductor includes a first number of windings; the second inductor includes a second number of windings; and the first number of windings is equal to the second number of windings.

In further features, the first and second numbers of windings are less than or equal to 20 windings.

In further features, the circuit board includes a printed circuit board.

In further features, the first, second, and third output conductors are printed on the printed circuit board.

In further features: the first inductor includes a first inductance; the second inductor includes a second inductance; and the first inductance is equal to the second inductance.

In further features, the first and second inductances are less than 0.5 microhenry (μH).

In further features, a transmission line includes: an inner conductor; an outer conductor that is coaxial with the inner conductor; an insulator that electrically insulates the outer conductor from the inner conductor; and the voltage/current probe, where the voltage/current probe is located in a cavity formed in a radially inner surface of the outer conductor.

In further features, a substrate processing system includes: an electrode including a first end and a second end; and the transmission line, where the inner conductor is electrically connected to the first end of the electrode, and where the outer conductor is electrically connected to the second end of the electrode.

In further features, a transformer includes: a primary winding including: a third inductor including a fifth end and a sixth end, the fifth end being electrically connected to the first output conductor; and a fourth inductor including a seventh end and an eighth end, the eighth end being electrically connected to the second output conductor, and the seventh end being electrically connected to the sixth end of the third inductor and the third output conductor; and a secondary winding.

In further features, a capacitor is electrically connected between the third output conductor and a ground potential.

In further features: a first analog to digital converter is configured to, based on an output of the secondary winding of the transformer, generate a first digital value corresponding to a current; and a second analog to digital converter is configured to, based on a voltage at the third output conductor, generate a second digital value corresponding to a voltage.

In further features, an impedance control module is configured to adjust an impedance of an impedance matching module based on the first digital value and the second digital value.

In a feature, a voltage/current probe includes: a circuit board that includes a first surface and a second surface that is opposite the first surface; a first inductor that is located on the first surface of the circuit board and that includes: a first end connected to a first output conductor; and a second end; a second inductor that is located on the second surface of the circuit board and that includes: a third end that is connected to a second output conductor; and a fourth end that is connected to the second end of the first inductor and to a third output conductor.

In further features: the first output conductor and the third output conductor are located on the first surface; and the second output conductor is located on the second surface.

In further features, the fourth end is connected to the second end of the first inductor through a via through the circuit board.

In further features: the first inductor includes a first number of windings; the second inductor includes a second number of windings; and the first number of windings is equal to the second number of windings.

In further features, the first and second numbers of windings are less than or equal to 20 windings.

In further features, the circuit board includes a printed circuit board.

In further features, the first, second, and third output conductors are printed on the printed circuit board.

In further features: the first inductor includes a first inductance; the second inductor includes a second inductance; and the first inductance is equal to the second inductance.

In further features, the first and second inductances are less than 0.5 microhenry (μH).

In further features, a transmission line includes: an inner conductor; an outer conductor that is coaxial with the inner conductor; an insulator that electrically insulates the outer conductor from the inner conductor; and the voltage/current probe, where the voltage/current probe is located in a cavity formed in a radially inner surface of the outer conductor.

In further features, a substrate processing system includes: an electrode including a first end and a second end; and the transmission line, where the inner conductor is electrically connected to the first end of the electrode, and where the outer conductor is electrically connected to the second end of the electrode.

In further features, a transformer includes: a primary winding including: a third inductor including a fifth end and a sixth end, the fifth end being electrically connected to the first output conductor; and a fourth inductor including a seventh end and an eighth end, the eighth end being electrically connected to the second output conductor, and the seventh end being electrically connected to the sixth end of the third inductor and the third output conductor; and a secondary winding.

In further features, a capacitor is electrically connected between the third output conductor and a ground potential.

In further features: a first analog to digital converter is configured to, based on an output of the secondary winding of the transformer, generate a first digital value corresponding to a current; and a second analog to digital converter is configured to, based on a voltage at the third output conductor, generate a second digital value corresponding to a voltage.

In further features, an impedance control module is configured to adjust an impedance of an impedance matching module based on the first digital value and the second digital value.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 includes a functional block diagram of an example substrate processing system including an electrostatic chuck (ESC);

FIG. 2 includes a functional block diagram of a portion of the substrate processing system;

FIG. 3 includes a cross sectional view of a transmission line including a voltage/current probe;

FIG. 4 is a functional block diagram of an example implementation of a radio frequency (RF) matching module;

FIG. 5 includes a schematic including an example implementation of a transformer and a voltage/current probe that measures voltage and current of a conductor;

FIG. 6 includes an example graph of a magnitude of voltage divided by current (V/I) versus frequency measured using a voltage/current probe; and

FIG. 7 includes an example graph of a magnitude of voltage divided by current (V/I) versus frequency measured using a voltage/current probe including Rogowski coils.

In the drawings, reference numbers may be reused to identify similar and/or identical elements.

### DETAILED DESCRIPTION

A controller of a semiconductor processing system controls power applied to an electrode based on a voltage and a current measured using a voltage/current probe. The voltage/current probe measures voltage and current in a transmission line that delivers radio frequency (RF) power to the electrode.

The voltage/current probe may include Rogowski coils that measure current through the transmission line and a ring type metallization that measures voltage through the transmission line. A Rogowski coil is an inductive pickup that is wound around an inner conductor of the transmission line. A Rogowski coil captures H-fields generated by the current flowing through the inner conductor. Because a hand-wound coil has large unit-to-unit variability, the coil may be printed on top and bottom layers of printed circuit board (PCB) and interconnected through vias.

To lower a quality factor of self-resonance of a Rogowski coil, embedded resistors may be connected between the turns of the Rogowski coil. If the quality factor is not lowered, errors in current measurement at one or more frequencies may occur. The ring type metallization capacitively senses the voltage from the inner conductor of the transmission line at the same location that the current is measured.

To avoid cross-talk between separate pick-ups, Faraday shielding of the current probe may be used. The Faraday shielding, however, may complicate the design and manufacturing of the voltage/current probe. To embed the Rogowski coils along with the ring type metallization in the transmission line, a relatively large cavity is made in the transmission line. The cavity, however, may perturb high frequency measurement, and decrease a dynamic range of an analog to digital converter that is configured to correct for the perturbation.

According to the present application, a voltage/current probe includes a first inductor and a second inductor. The first inductor is wound in a first direction and is located on a first surface of an electrical connection system structure. In some embodiments, the electrical connection system structure may include a circuit board, such as a printed circuit board. Additionally or alternatively, other structures configured to electrically connect electronic components and/or mechanically support electronic components may be used. The second inductor is wound in a second direction that is opposite to the first direction and is located on a second surface of the electrical connection system structure that is opposite the first surface. The voltage/current probe is located in a cavity in an outer conductor of the transmission line. The first and second inductors measure both current and voltage of the inner conductor of the transmission line.

Because the first and second inductors are wound in opposite directions, nearby H-fields from noise sources cancel. The differential output of the first and second inductors provides the current measurements. The common mode signal (at the node between the first and second inductors) provides the voltage measurements. Thus, voltage and current are both measured using the same voltage/current probe. This is in contrast to other types of voltage/current probes where Rogowski coils measure current while a ring type metallization measures voltage.

The first and second inductors connected in series capture the H-field generated by the current flowing through the inner conductor of the transmission line. The E-field from the inner conductor of the transmission line capacitively couples to the body of the first and second inductors for the measurement of the voltage at the node between the first and second inductors. The voltage/current probe has a lower cost than other types of voltage/current probes and has a flatter response than other types of voltage/current probes.

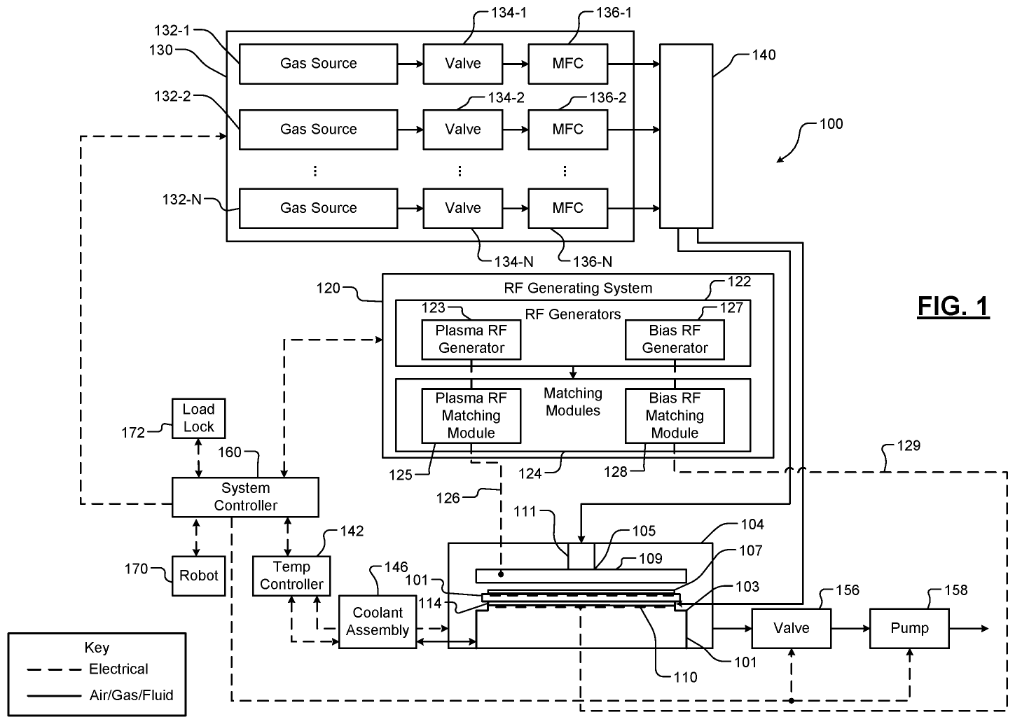

FIG. 1 includes a functional block diagram of an example substrate processing system 100 including an electrostatic chuck (ESC) 101. Although FIG. 1 shows a capacitive coupled plasma (CCP) system, the present application is also applicable to other types of processing systems and plasma processing systems. The ESC 101 electrostatically clamps substrates to the ESC 101 for processing.

The substrate processing system 100 includes a processing chamber 104. The ESC 101 is enclosed within the processing chamber 104. The processing chamber 104 also encloses other components, such as an upper electrode 105, and contains radio frequency (RF) plasma. During operation, a substrate 107 (e.g., a semiconductor wafer) is arranged on and electrostatically clamped to the ESC 101.

A showerhead 109 that introduces and distributes gases may include or serve as the upper electrode 105. The showerhead 109 may include a stem portion 111 including one end connected to a top surface of the processing chamber 104. The showerhead 109 is generally cylindrical and extends radially outward from an opposite end of the stem portion 111 at a location that is spaced from the top surface of the processing chamber 104. A substrate-facing surface of the showerhead 109 includes holes through which gas flows for processing. Alternately, the upper electrode 105 may include a conducting plate and the gases may be introduced in another manner.

A baseplate 103 includes a lower (bias) electrode 110. One or both of the ESC 101 and the baseplate 103 may include temperature control elements (TCEs). An intermediate layer 114 may be arranged between the ESC 101 and the baseplate 103. The intermediate layer 114 may bond or otherwise adhere the ESC 101 to the baseplate 103. As an example, the intermediate layer 114 may be formed of an adhesive material suitable for bonding the ESC 101 to the baseplate 103.

The baseplate 103 may include one or more gas channels and/or one or more coolant channels. The gas channels may flow backside gas to a backside of the substrate 107. The coolant channels flow coolant through the baseplate 103.

An RF generating system 120 generates and outputs RF voltages to the upper electrode 105 and the lower electrode 110. One of the upper electrode 105 and the lower electrode 110 may be DC grounded, AC grounded, or at a floating potential. For example only, the RF generating system 120 may include one or more RF generators 122 that generate RF voltages. The output of the RF generator(s) 122 are fed by one or more matching modules 124 to the upper electrode 105 and/or the lower electrode 110. The matching modules 124 are configured to match their impedances to the impedances of the upper and lower electrodes 105 and 110, such as to minimize reflection.

As an example, a plasma RF generator 123 generates power to be applied to the upper electrode 105. A plasma RF matching module 125 impedance matches the power from the plasma RF generator 123 to the impedance of the upper electrode 105 and applies the (impedance matched) power to the upper electrode 105 via a first transmission line 126. A bias RF generator 127 generates power to be applied to the lower electrode 110. A bias RF matching module 128 impedance matches the power from the bias RF generator 127 to the impedance of the lower electrode 110 and applies the (impedance matched) power to the lower electrode 110 via a second transmission line 129.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas, and/or purge gas. Vaporized precursor may also be used.

The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 104. For example only, the output of the manifold 140 may be fed to the showerhead 109.

The substrate processing system 100 may include a cooling system that includes a temperature controller 142. Although shown separately from a system controller 160, the temperature controller 142 may be implemented as part of the system controller 160. The baseplate 103 may include a plurality of temperature controlled zones (e.g., 4 zones), where each of the temperature controlled zones includes one or more temperature sensors and one or more temperature control elements (TCEs). The temperature controller 142 may control operation of the TCEs of a zone based on the temperature(s) measured by the temperature sensor(s) of that zone.

The temperature controller 142 may also control a flow rate of backside gas to the gas channels from one or more of the gas sources 132. The temperature controller 142 may also control a temperature and a flowrate of coolant flowing through the coolant channels via a coolant assembly 146. The coolant assembly 146 may include a coolant pump that pumps coolant from a reservoir to the coolant channels. The coolant assembly 146 may also include a heat exchanger that transfers heat away from the coolant, such as to air. The coolant may be, for example, a liquid coolant.

A valve 156 and pump 158 may be used to evacuate reactants from the processing chamber 104. A robot 170 may deliver substrates onto and remove substrates from the ESC 101. For example, the robot 170 may transfer substrates between the ESC 101 and a load lock 172. The system controller 160 may control operation of the robot 170. The system controller 160 may also control operation of the load lock 172.

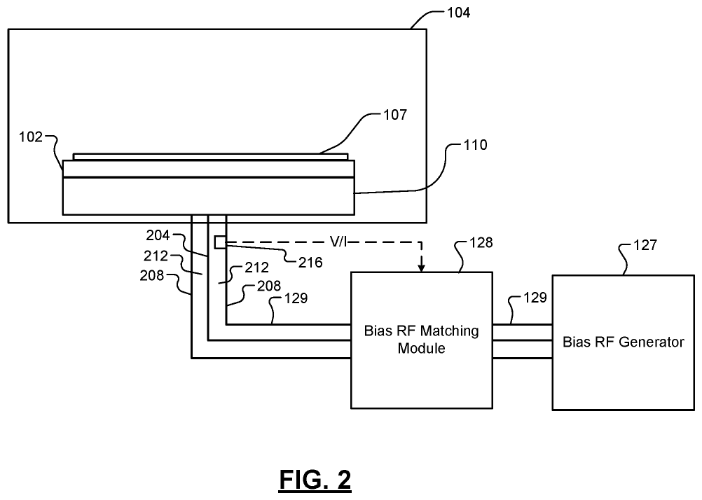

FIG. 2 includes a functional block diagram of a portion of the substrate processing system 100. The second transmission line 129 includes an inner conductor 204 and an outer conductor 208. The inner conductor 204 is connected to one end of the lower electrode 110 a ground potential of the processing chamber 104. An insulator 212 (e.g., air, a dielectric, etc.) electrically insulates (isolates) the inner conductor 204 and the outer conductor 208. For example only, the second transmission line 129 may include a coaxial cable.

The bias RF matching module 128 adjusts its impedance and the power applied to the lower electrode 110 based on voltage and current measured by a voltage/current (V/I) probe 216. The voltage/current probe 216 is located in a cavity formed in the outer conductor 208. While the example of the bias RF matching module 128 and the second transmission line 129 are discussed herein, a voltage/current probe may additionally or alternatively be provided for the first transmission line 126, and the plasma RF matching module 125 may adjust its impedance and the power applied to the upper electrode 105 based on voltage and current measured by the voltage/current probe of the first transmission line 126.

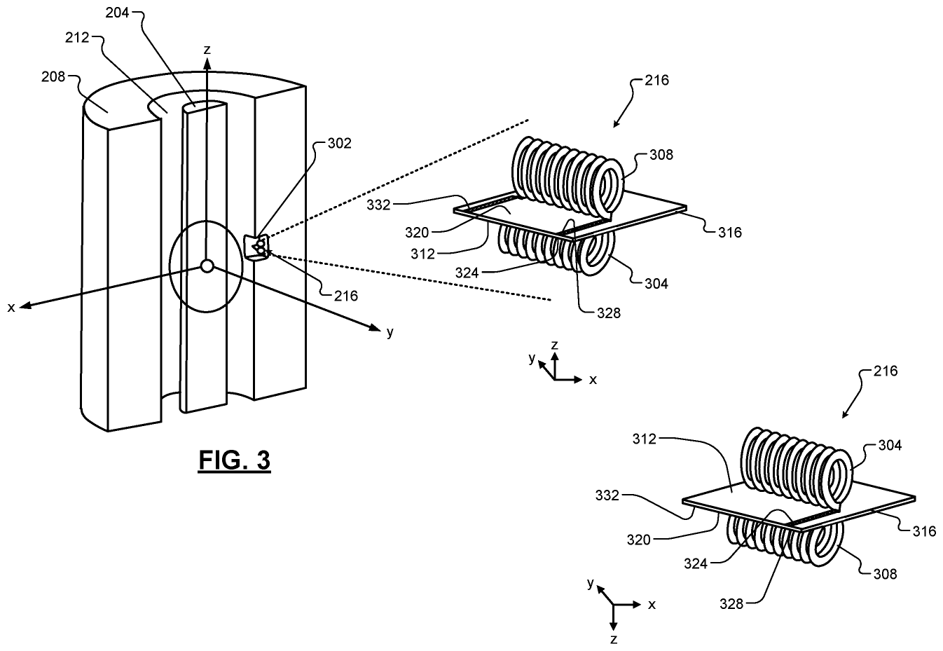

FIG. 3 is a cross sectional view of a portion of the second transmission line 129 including the voltage/current probe 216. As shown, the voltage/current probe 216 is disposed within a cavity 302 formed in an inner surface of the outer conductor 208 of the second transmission line 129. The voltage/current probe 216 does not encircle the second transmission line 129 or the first transmission line 126.

The voltage/current probe 216 includes a first inductor 304 and a second inductor 308. The first inductor 304 is located on a first surface 312 of a circuit board 316. The circuit board 316 may be, for example, a printed circuit board (PCB) or another suitable type of circuit board. The second inductor 308 is located on a second surface 320 of the circuit board 316 that is opposite the first surface 312. The first and second inductors 304 and 308 are located the same distance from the inner conductor 204. In various implementations, both of the first and second inductors 304 and 308 may be located on the same surface of the circuit board 316 facing the inner conductor 204.

The first inductor 304 is wound in one of a clockwise direction and a counterclockwise direction. The second inductor 308 is wound in the opposite direction as the first inductor 304. In other words, the second inductor 308 is wound in the other one of the clockwise direction and the counterclockwise direction. The first and second inductors 304 and 308 may have the same inductance. For example, the first and second inductors 304 and 308 may have inductances that are less than 0.5 microhenry (μH), such as 0.1 pH.

The first and second inductors 304 and 308 capture H-field generated by current flowing through the inner conductor 204. H-fields from noise sources, however, cancel due to the first and second inductors 304 and 308 being wound in opposite directions. E-field from the inner conductor 204 is received by the bodies (metallization) of the first and second inductors 304 and 308.

The first and second inductors 304 and 308 may have the same number of turns or different numbers of turns. For example only, the first and second inductors 304 and 308 may each have less than 20 turns, such as 10 turns or another suitable number of turns. The number of turns of each of the first and second inductors 304 and 308 may be selected, for example, based on a predetermined frequency range of interest. The predetermined frequency range of interest may be greater than 80 kilohertz (kHz), for example, approximately 100 kHz to approximately 500 megahertz (MHz) or another suitable frequency range.

A first end of the first inductor 304 is connected to a first output 324 of the voltage/current probe 216. A second end of the first inductor 304 is connected to a first end of the second inductor 308, such as through a via through the circuit board 316. A second end of the second inductor 308 is connected to a second output 328 of the voltage/current probe 216. A third output 332 is connected to the node between the first inductor 304 and the second inductor 308. The first output 324 may extend along the first surface 312 of the circuit board 316. The second output 328 and the third output 332 may extend along the second surface 320 of the circuit board 316.

The first, second, and third outputs 324, 328, and 332 extend through the outer conductor 208 to the bias RF matching module 128. The first, second, and third outputs 324, 328, and 332, however, are electrically insulated from the outer conductor 208. The current through the inner conductor 204 is measured via the first and second outputs 324 and 328. The voltage of the inner conductor is measured via the third output 332.

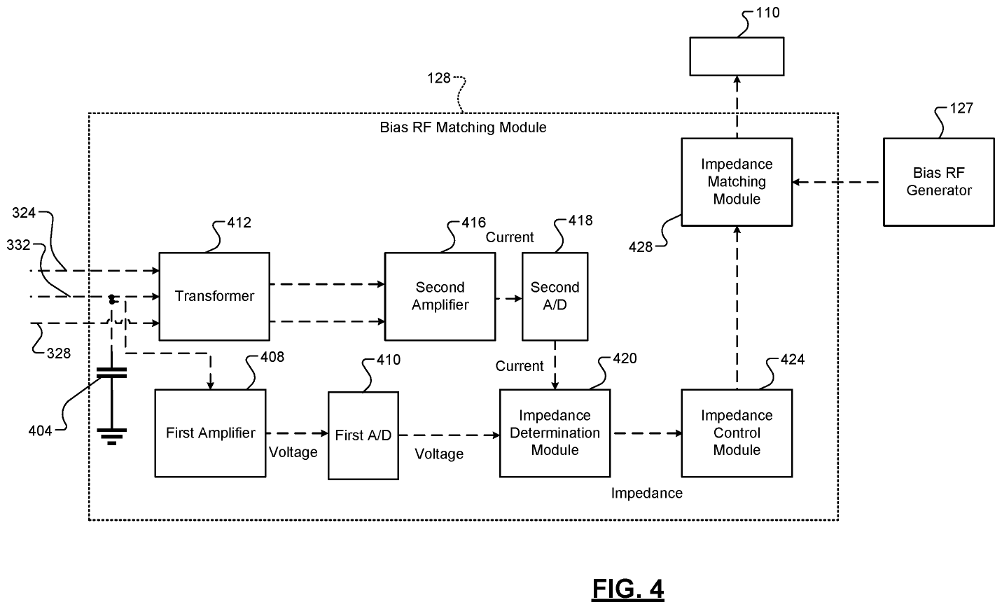

FIG. 4 is a functional block diagram of an example implementation of the bias RF matching module 128. A capacitor 404 is connected between the third output 332 and a ground potential. The capacitor 404 may have a capacitance that is less than 500 picofarads (pF), such as 300 pF. The capacitor 404 may attenuate signals to a level of interest.

A first amplifier 408 amplifies a voltage across the capacitor 404. The output of the first amplifier 408 corresponds to the voltage of the inner conductor 204. A first analog to digital converter (A/D) 410 converts the output of the first amplifier 408 into a digital value corresponding to the voltage of the inner conductor 204.

The first and second outputs 324 and 328 are connected to a transformer 412. A center tap of a primary coil of the transformer 412 may be connected to the third output 332. By connecting the third output 332 to the center tap, the capacitive coupling present at the other two terminals of the transformer 412 cancel with this third output 332 to minimize cross-talk.

A second amplifier 416 amplifies an output of the transformer 412. The output of the second amplifier 416 corresponds to the current through the inner conductor 204. In various implementations, the first and second amplifiers 408 and 416 may be omitted. A second analog to digital converter (A/D) 418 converts the output of the second amplifier 416 into a digital value corresponding to the current of the inner conductor 204. Voltage and current are isolated via this arrangement, and no Faraday shielding may be required.

An impedance determination module 420 determines an impedance (e.g., a complex impedance) of the lower electrode 110 based on the voltage of the inner conductor 204 and the current through the inner conductor 204. The impedance determination module 420 may determine the impedance, for example, using one or more lookup tables and/or equations that relate voltage and current of the inner conductor 204 to impedance.

An impedance control module 424 adjusts an impedance of an impedance matching module 428 based on the impedance of the lower electrode 110. More specifically, the impedance control module 424 adjusts the impedance of the impedance matching module 428 to match the impedance of the impedance matching module 428 to the impedance of the lower electrode 110.

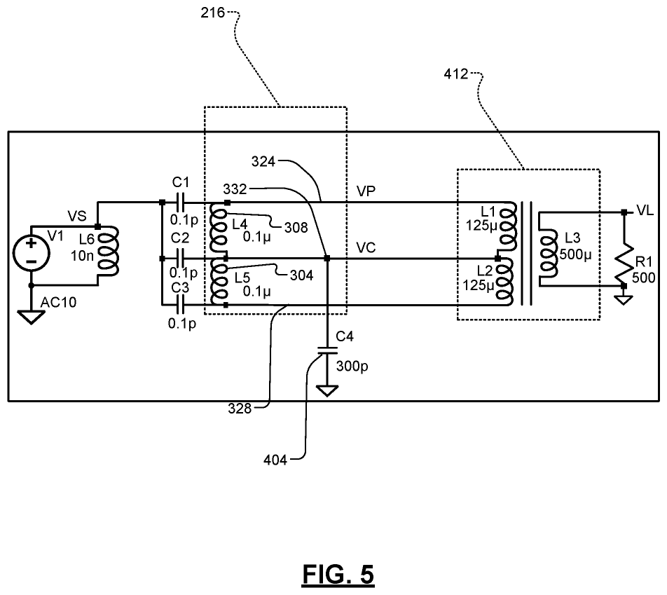

FIG. 5 includes a schematic including an example implementation of the voltage/current probe 216 that measures voltage (VC) and current (VL) of the inner conductor 204 and the transformer 412. Capacitors C1, C2, and C3 represent capacitive coupling between the inner conductor 204 and the first and second inductors 304 and 308. The k-factor (K) represents the H-field captured by the first and second inductors 304 and 308 for current sensing. The transformer 412 is denoted by inductors L1, L2, and L3. The shielding capability depends on the common mode rejection capability of the transformer 412. The capacitor 404 (C4) forms the second leg of a capacitive divider which is used to measure the voltage.

Because the voltage/current probe 216 does not include complicated layers of PCB and/or hand-winding around a magnetic core, an overall cost of the voltage/current probe 216 may be less than other types of voltage/current probes, such as voltage/current probes including Rogowski coils. The voltage/current probe 216 does not include any turn to turn embedded resistors as self-resonance of the first and second inductors 304 and 308 is greater (e.g., greater than 1 gigahertz GHz) than the predetermined frequency range of interest.

An overall size of the cavity 302 required to house the voltage/current probe 216 may be smaller than that of other types of voltage/current probes, such as voltage/current probes including Rogowski coils. The cavity 302 does not perturb measurements at frequencies within the predetermined frequency range of interest. Errors and perturbations may be minimal across the predetermined frequency range of interest. A dynamic range of an A/D converter may therefore be maximized.

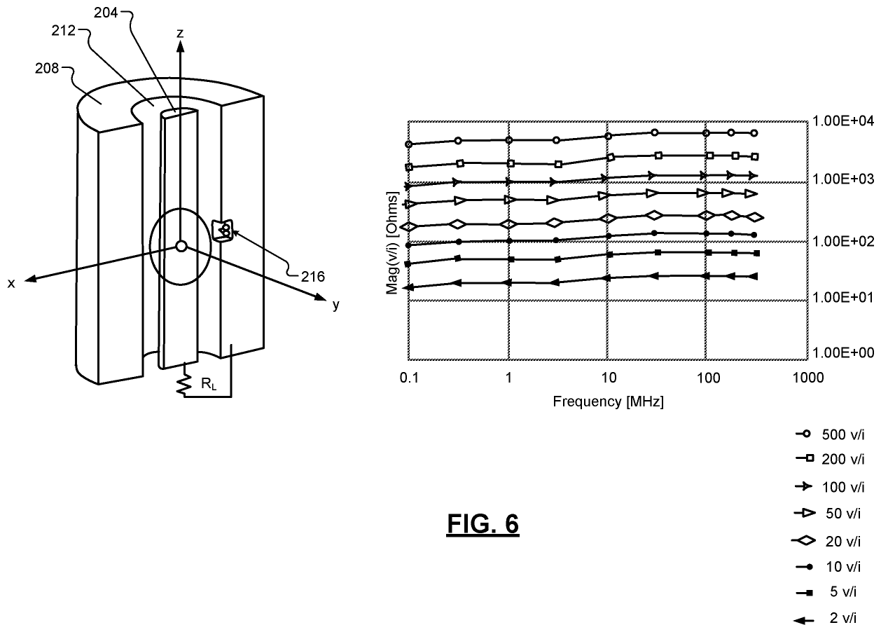

FIG. 6 illustrates an example implementation with a resistive load (RL) connected across the second transmission line 129 in place of the lower electrode 110. The second transmission line 129 and the lower electrode 110 are shown, for example, in FIG. 2. FIG. 6 also includes an example graph of a magnitude of voltage divided by current (V/I) versus frequency measured using the voltage/current probe 216.

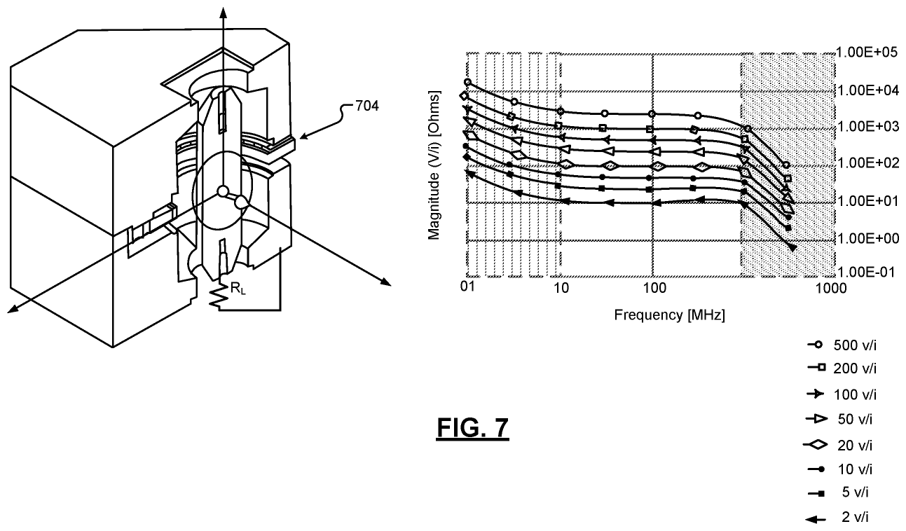

FIG. 7 includes an example graph of (V/I) versus frequency measured using another type of voltage/current probe 704 including Rogowski coils. As illustrated by FIG. 6, the voltage/current probe 216 produces a flatter performance than other types of voltage/current probes. Thus, the voltage/current probe 216 will require lesser dynamic range to correct for unintended perturbations in the output of the voltage/current probe 216.

The voltage/current probe 216 can be used in various different types of substrate processing systems. For example only, the voltage/current probe 216 may be used in plasma processing systems, plasma assisted processing systems, conductor etching systems, dielectric etching systems, deposition systems, etc.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A voltage/current probe comprising:
a circuit board;
a first inductor that is located on the circuit board, that is wound in a first direction, and that includes:
a first end connected to a first output conductor; and
a second end;
a second inductor that is located on the circuit board, that is wound in a second direction that is opposite the first direction, and that includes:
a third end that is connected to a second output conductor; and
a fourth end that is connected to the second end of the first inductor and to a third output conductor.

2. The voltage/current probe of claim 1 wherein:
the circuit board includes a first surface and a second surface that is opposite the first surface;
the first inductor is located on the first surface; and
the second inductor is located on the second surface.

3. The voltage/current probe of claim 2 wherein:
the first output conductor and the third output conductor are located on the first surface; and
the second output conductor is located on the second surface.

4. The voltage/current probe of claim 2 wherein the fourth end is connected to the second end of the first inductor through a via through the circuit board.

5. The voltage/current probe of claim 1 wherein:
the first inductor includes a first number of windings;
the second inductor includes a second number of windings; and
the first number of windings is equal to the second number of windings.

6. The voltage/current probe of claim 5 wherein the first and second numbers of windings are less than or equal to 20 windings.

7. The voltage/current probe of claim 1 wherein the circuit board includes a printed circuit board.

8. The voltage/current probe of claim 7 wherein the first, second, and third output conductors are printed on the printed circuit board.

9. The voltage/current probe of claim 1 wherein:
the first inductor includes a first inductance;
the second inductor includes a second inductance; and
the first inductance is equal to the second inductance.

10. The voltage/current probe of claim 9 wherein the first and second inductances are less than 0.5 microhenry (μH).

11. A transmission line including:
an inner conductor;
an outer conductor that is coaxial with the inner conductor;
an insulator that electrically insulates the outer conductor from the inner conductor; and
the voltage/current probe of claim 1, wherein the voltage/current probe is located in a cavity formed in a radially inner surface of the outer conductor.

12. A substrate processing system comprising:
an electrode including a first end and a second end; and
the transmission line of claim 11,
wherein the inner conductor is electrically connected to the first end of the electrode, and
wherein the outer conductor is electrically connected to the second end of the electrode.

13. The substrate processing system of claim 12 further comprising a transformer including:
a primary winding including:
a third inductor including a fifth end and a sixth end, the fifth end being electrically connected to the first output conductor; and
a fourth inductor including a seventh end and an eighth end, the eighth end being electrically connected to the second output conductor, and the seventh end being electrically connected to the sixth end of the third inductor and the third output conductor; and
a secondary winding.

14. The substrate processing system of claim 13 further comprising a capacitor that is electrically connected between the third output conductor and a ground potential.

15. The substrate processing system of claim 13 further comprising:
a first analog to digital converter configured to, based on an output of the secondary winding of the transformer, generate a first digital value corresponding to a current; and
a second analog to digital converter configured to, based on a voltage at the third output conductor, generate a second digital value corresponding to a voltage.

16. The substrate processing system of claim 15 further comprising an impedance control module configured to adjust an impedance of an impedance matching module based on the first digital value and the second digital value.

17. A voltage/current probe comprising:
a circuit board that includes a first surface and a second surface that is opposite the first surface;
a first inductor that is located on the first surface of the circuit board and that includes:
a first end connected to a first output conductor; and
a second end;
a second inductor that is located on the second surface of the circuit board and that includes:
a third end that is connected to a second output conductor; and
a fourth end that is connected to the second end of the first inductor and to a third output conductor.

18. The voltage/current probe of claim 17 wherein:
the first output conductor and the third output conductor are located on the first surface; and
the second output conductor is located on the second surface.

19. The voltage/current probe of claim 17 wherein the fourth end is connected to the second end of the first inductor through a via through the circuit board.

20. The voltage/current probe of claim 17 wherein:
the first inductor includes a first number of windings;
the second inductor includes a second number of windings; and
the first number of windings is equal to the second number of windings.

21. The voltage/current probe of claim 20 wherein the first and second numbers of windings are less than or equal to 20 windings.

22. The voltage/current probe of claim 17 wherein the circuit board includes a printed circuit board.

23. The voltage/current probe of claim 22 wherein the first, second, and third output conductors are printed on the printed circuit board.

24. The voltage/current probe of claim 17 wherein:
the first inductor includes a first inductance;
the second inductor includes a second inductance; and
the first inductance is equal to the second inductance.

25. The voltage/current probe of claim 24 wherein the first and second inductances are less than 0.5 microhenry (μH).

26. A transmission line including:
an inner conductor;
an outer conductor that is coaxial with the inner conductor;
an insulator that electrically insulates the outer conductor from the inner conductor; and
the voltage/current probe of claim 17, wherein the voltage/current probe is located in a cavity formed in a radially inner surface of the outer conductor.

27. A substrate processing system comprising:
an electrode including a first end and a second end; and
the transmission line of claim 26,
wherein the inner conductor is electrically connected to the first end of the electrode, and
wherein the outer conductor is electrically connected to the second end of the electrode.

28. The substrate processing system of claim 27 further comprising a transformer including:
a primary winding including:
a third inductor including a fifth end and a sixth end, the fifth end being electrically connected to the first output conductor; and
a fourth inductor including a seventh end and an eighth end, the eighth end being electrically connected to the second output conductor, and the seventh end being electrically connected to the sixth end of the third inductor and the third output conductor; and
a secondary winding.

29. The substrate processing system of claim 28 further comprising a capacitor that is electrically connected between the third output conductor and a ground potential.

30. The substrate processing system of claim 28 further comprising:
a first analog to digital converter configured to, based on an output of the secondary winding of the transformer, generate a first digital value corresponding to a current; and
a second analog to digital converter configured to, based on a voltage at the third output conductor, generate a second digital value corresponding to a voltage.

31. The substrate processing system of claim 30 further comprising an impedance control module configured to adjust an impedance of an impedance matching module based on the first digital value and the second digital value.
